(19) United States
(12) Patent Application Publication
(10) Pub. No.: US 2019/0113847 A1
(43) Pub. Date: Apr. 18, 2019

(54) CONTROL METHOD OF EXPOSURE APPARATUS AND CONTROL APPARATUS OF EXPOSURE APPARATUS

(71) Applicant: SAMSUNG ELECTRONICS CO., LTD., Suwon-si (KR)

(72) Inventors: Sung-Min AHN, Suwon-si (KR); Ja-Yul KIM, Seoul (KR); Sang-Ha PARK, Hwaseong-si (KR); Sang-Hyun PARK, Yongin-si (KR); Sang-Su YEH, Suwon-si (KR)

(21) Appl. No.: 16/029,187

(22) Filed: Jul. 6, 2018

(30) Foreign Application Priority Data
Oct. 18, 2017 (KR) 10-2017-0135459

(51) Int. Cl. G03F 7/20; G02B 26/08

(52) U.S. Cl. CPC G03F 7/201; G03F 7/70641; G02B 26/0891

(57) ABSTRACT

In a method of controlling an exposure apparatus, a plurality of spot beams is irradiated from an optical system onto a reference surface. Focal positions of at least some spot beams of the plurality of spot beams on Z axis perpendicular to the reference surface are obtained. A focal plane of the at least some spot beams is calculated from the focal positions. An angle of the optical system relative to the reference surface is aligned based on an angle error between the focal plane and the reference surface.

### CROSS-REFERENCE TO RELATED APPLICATION

Korean Patent Application No. 10-2017-0135459, filed on Oct. 18, 2017, in the Korean Intellectual Property Office, and entitled: “Control Method of Exposure Apparatus and Control Apparatus of Exposure Apparatus,” is incorporated by reference herein in its entirety.

### BACKGROUND

### 1. Field

Example embodiments relate to a control method of an exposure apparatus and a control apparatus of an exposure apparatus. More particularly, example embodiments relate to a control method of an exposure apparatus for aligning an optical system of a maskless exposure apparatus and a control apparatus of an exposure apparatus for performing the same.

### 2. Description of the Related Art

An exposure apparatus may be used for forming a pattern on a substrate such as a flat panel display (FPD) or a semiconductor wafer. As the size of the substrate increases and the pattern to be formed requires increased precision, manufacturing costs of a photomask increase. A maskless exposure apparatus may achieve reduced costs. This maskless exposure apparatus may use a bundle of spot beams irradiated from an optical system having a spatial light modulator (SLM) to expose a pattern. However, because the optical system has a relatively high aspect ratio, a focal surface of the spot beams may not be aligned parallel with a surface of the substrate to be exposed.

### SUMMARY

According to example embodiments, in a method of controlling an exposure apparatus, a plurality of spot beams is irradiated from an optical system onto a reference surface. Focal positions of at least some spot beams of the plurality of spot beams on Z axis perpendicular to the reference surface are obtained. A focal plane of the at least some spot beams is calculated from the focal positions. An angle of the optical system is aligned based on an angle error between the focal plane and the reference surface.

According to example embodiments, in a method of controlling an exposure apparatus, a plurality of spot beams is irradiated from an optical system onto a reference surface. The plurality of spot beams are scanned in a Z axis respectively to obtain information of at least some spot beams of the plurality of spot beams on the Z axis perpendicular to the reference surface. Focal positions are determined on an optical axis from the information of the at least some spot beams. A focal plane of the at least some spot beams is calculated from the focal positions. An angle of the optical system is aligned based on an angle error between the focal plane and the reference surface.

According to example embodiments, an apparatus of controlling an exposure apparatus, includes a beam measurement system to measure focal positions of at least some spot beams of a plurality of spot beams irradiated from an optical system on Z axis perpendicular to an object surface, a controller to calculate a focal plane of the spot beams from the measured focal positions and output an alignment control signal based on an angle error between the focal plane and the object surface for controlling an angle of the optical system, and an alignment actuator to adjust the angle of the optical system according to the alignment control signal.

### BRIEF DESCRIPTION OF THE DRAWINGS

Features will become apparent to those of skill in the art by describing in detail exemplary embodiments with reference to the attached drawings in which:

FIG. 1 illustrates a block diagram of a maskless exposure apparatus in accordance with example embodiments.

FIG. 2 illustrates a cross-sectional view of the maskless exposure apparatus in FIG. 1.

FIG. 3 illustrates a perspective view of a bundle of spot beams irradiated from an optical system of the maskless exposure apparatus in FIG. 1.

FIG. 4 illustrates image information of a portion of the spot beams in FIG. 3, which are irradiated onto a surface of an object.

FIG. 5 illustrates image information of the spot beams measured by a beam measurement system of the maskless exposure apparatus in FIG. 1.

FIG. 6 illustrates a block diagram of a controller of the maskless exposure apparatus in FIG. 1.

FIGS. 7A and 7B illustrate views of prism optical device of the maskless exposure apparatus in FIG. 1.

FIG. 8 illustrates a view of an alignment actuator of the maskless exposure apparatus in FIG. 1.

FIG. 9 illustrates a flow chart of a control method of an exposure apparatus in accordance with example embodiments.

FIG. 10 illustrates a graph of a diameter of a spot beam with respect to Z axis position.

FIG. 11 illustrates a graph of an intensity of a spot beam with respect to Z axis position.

FIG. 12 illustrates a graph of a focal plane calculated from focal positions.

FIG. 13 illustrates a graph of an alignment movement amount determined using a normal vector of the focal plane.

### DETAILED DESCRIPTION

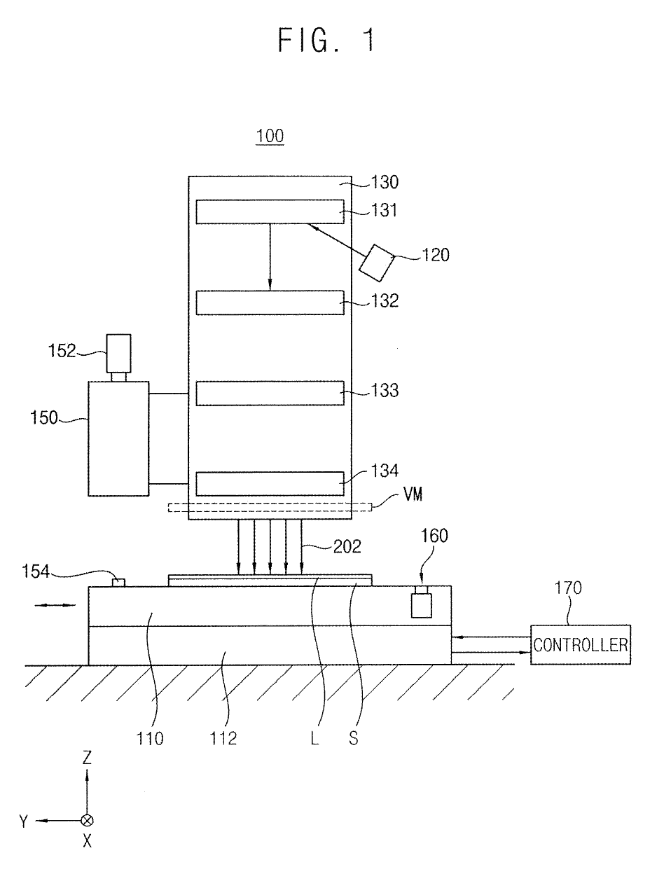

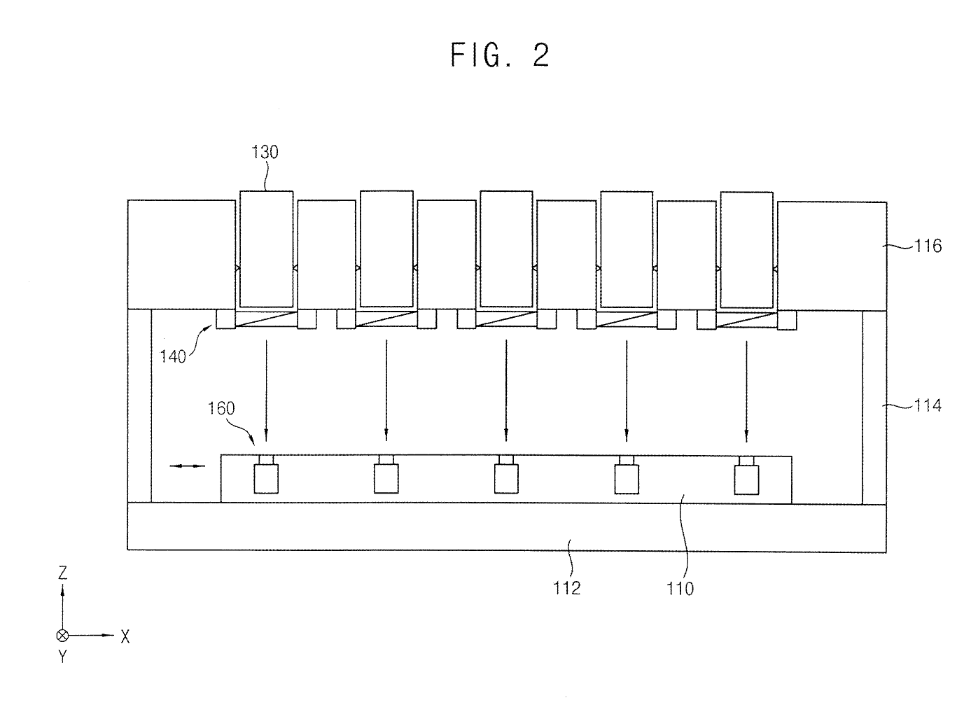

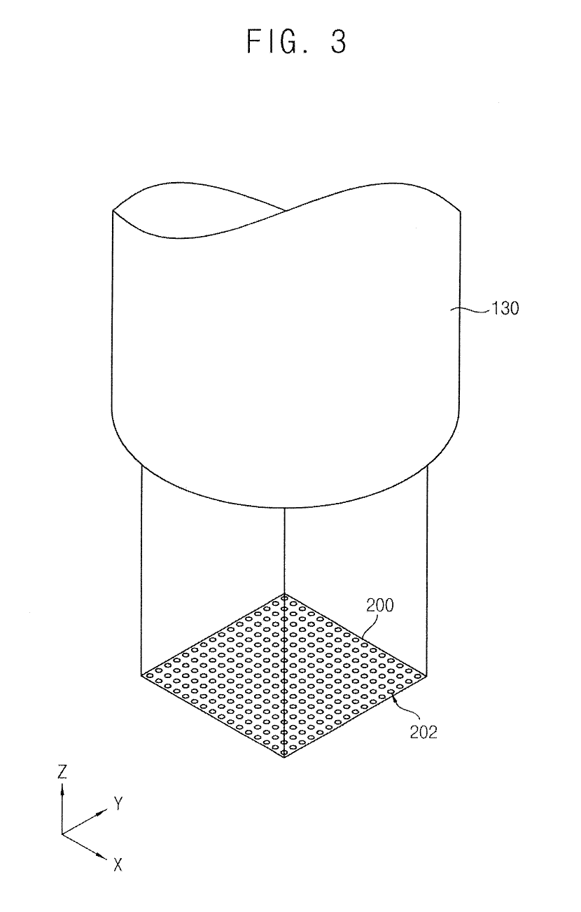

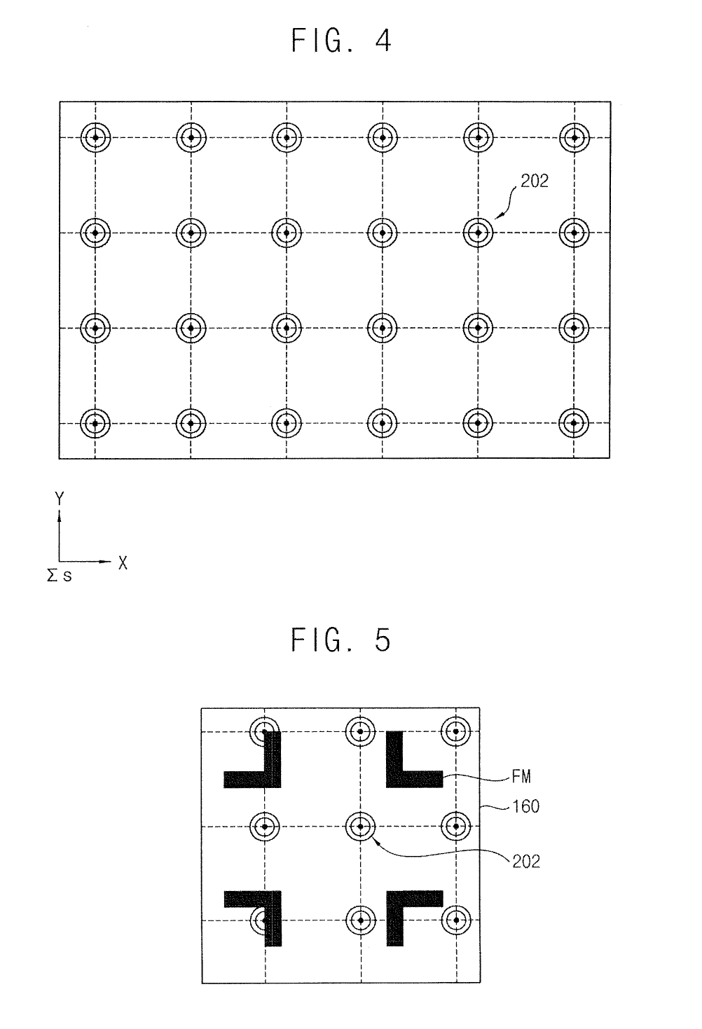

FIG. 1 is a block diagram illustrating a maskless exposure apparatus in accordance with example embodiments. FIG. 2 is a cross-sectional view illustrating the maskless exposure apparatus in FIG. 1. FIG. 3 is a perspective view illustrating a bundle of spot beams irradiated from an optical system of the maskless exposure apparatus in FIG. 1. FIG. 4 is image information illustrating a portion of the spot beams in FIG. 3, which are irradiated onto a surface of an object. FIG. 5 is image information illustrating the spot beams measured by a beam measurement system of the maskless exposure apparatus in FIG. 1.

Referring to FIGS. 1 to 5, a maskless exposure apparatus 100 may include a stage to support a substrate S, an optical system 130 located over the stage to irradiate a plurality of spot beams 202 in order to expose the substrate with a pattern, a beam measurement system 160 to measure the spot beams, and a controller to control the stage and the optical system 130.

In example embodiments, the maskless exposure apparatus 100 may be a pattern generator for writing a pattern on the substrate S having a photosensitive layer L deposited thereon. The maskless exposure apparatus 100 may be used for a photolithography process, e.g., on a flat panel display (FPD) or a semiconductor wafer.

The stage may include a stage driving portion 112 and a movable table 110 installed movable on the stage driving portion 112 to support the substrate S. The movable table 110 may be movable in a first direction (X direction) and a second direction (Y direction) on the stage driving portion 112. The stage may include the stage driving portion 112 for moving the movable table 110 and the controller 170 may control the stage driving portion to move the movable table 110.

In example embodiments, a plurality of the optical systems 130 may be installed over the stage. A head supporting plate 116 may be coupled to a stage gantry 114 to support a multiple exposure head as a multi-optical system. The optical systems 130 may be arranged over the stage to be spaced apart from each other in the first direction (X direction). The multiple exposure head may include a plurality of prism optical devices 140, e.g., in one-to-one correspondence with the optical system 130. The multiple exposure head including the plurality of the optical systems 130 may receive spatially modulated beams from a light emitted from a light source 120 so as to irradiate the beams on the substrate S.

In particular, the optical system 130 may expose the substrate S with a plurality of the spot beams to form a pattern of a virtual mask (VM). The optical system 130 may include a light modulation element 131 to modulate the light emitted from the light source 120 into the light having the mask pattern (VM) and a projection optical system to project the modulated light into a plurality of the spot beams onto a surface of the substrate S.

The projection optical system may include a first projection lens 132 to magnify the modulated light, a multi lens array (MLA) 133 having a plurality of micro lenses to separate the magnified light into a plurality of the spot beams and to collimate the spot beams, and a second projection lens 134 to adjust the resolution of the spot beams and to transmit the adjusted spot beams.

For example, the light modulation element 131 may include a spatial light modulator (SLM). The light modulation element 131 may include a micro-opto-electromechanical system (MOEMS) type digital micro-mirror device (DMD). A DMD includes a memory cell and a plurality of micro mirrors arranged in a matrix, and the controller 170 may output an exposure control signal for controlling ON/OFF of each micro mirror. According to other embodiments, the SLM may include transmissive modulators and the light source 120 may be above the SLM. The plurality of micro lenses may be arranged in a one-to-one correspondence to the plurality of micro mirrors. For example, when the light modulation element 131 includes 1920×400 micro mirrors, the multi lens array 133 may include 1920×400 micro lenses correspondingly.

As illustrated in FIG. 3, the optical system 130 may irradiate a plurality of spot beams 202 onto the substrate S to generate a virtual mask pattern (VM). The spot beams 202 may be irradiated to form an exposure surface 200 on the surface of the object. The virtual mask pattern (VM) may not be a physical mask, and may be formed by a pattern of a plurality of the spot beams turned on/off by the light modulation element 131 corresponding to the exposure control signal.

In example embodiments, an alignment system 150 may be provided above the stage. A mark photographing unit 152 may photograph an alignment mark 154 on the movable table 110 and transmit a photographed image to the controller 170. The controller 170 may determine a movement amount of the movable table 110 and control the stage driving portion to move the movable table 110 according to the determined movement amount.

In example embodiments, the beam measurement system (BMS) 160 may be provided in the movable table 110 to measure spot beams irradiated from the optical system 130. A plurality of the beam measurement systems 160 may be installed corresponding to the optical systems 130, e.g., in a one-to-one correspondence thereto. The beam measurement systems 160 may be arranged to be spaced apart from each other in the first direction (X direction) and the second direction (Y direction) corresponding to the optical systems 130. A fiducial BMS mark array (FBA) having an array of a plurality of fiducial marks (FMs) engraved thereon, may be mounted on the beam measurement system 160.

The beam measurement system 160 may be movable with the movable table 110 in the first direction (X direction) and the second direction (Y direction), and may include 2D image device, e.g., CCD camera, to photograph the spot beams. The beam measurement system 160 may be finely adjusted in XY plane. The beam measurement system 160 may be movable in an optical axis direction (Z direction), e.g., separate from the movement of the movable table 110, and may measure a focal height of the spot beam (focal position on the Z axis).

The controller 170 may determine position coordinates (X, Y coordinate values) of the respective beam measurement systems 160 using a plurality of the fiducial marks (FMs) of the fiducial BMS mark array (FBA). The controller 170 may obtain the position coordinates of the respective beam measurement systems 160 by aligning the center of the beam measurement system 160 with the center of the fiducial mark (FM) of the fiducial BMS mark array (FBA) through the XY fine adjustment of the beam measurement system 160.

As illustrated in FIGS. 4 and 5, the position of the spot beam in a stage coordinate system (E s) may be measured by image information of the measured spot beam. For example, the movable table 110 may be moved such that the spot beams irradiated onto the fiducial mark (FM) are located within the fields of view (FOVs) of the beam measurement system 160, and then the positions of the spot beams irradiated from the respective optical systems 130 may be measured.

The controller 170 may generate mask data from the position coordinate of the beam measurement system 160 and the position of the spot beam measured by the beam measurement system and control the optical system 130 to form a mask pattern.

Hereinafter, a control apparatus for controlling an optical system of the maskless exposure apparatus will be explained.

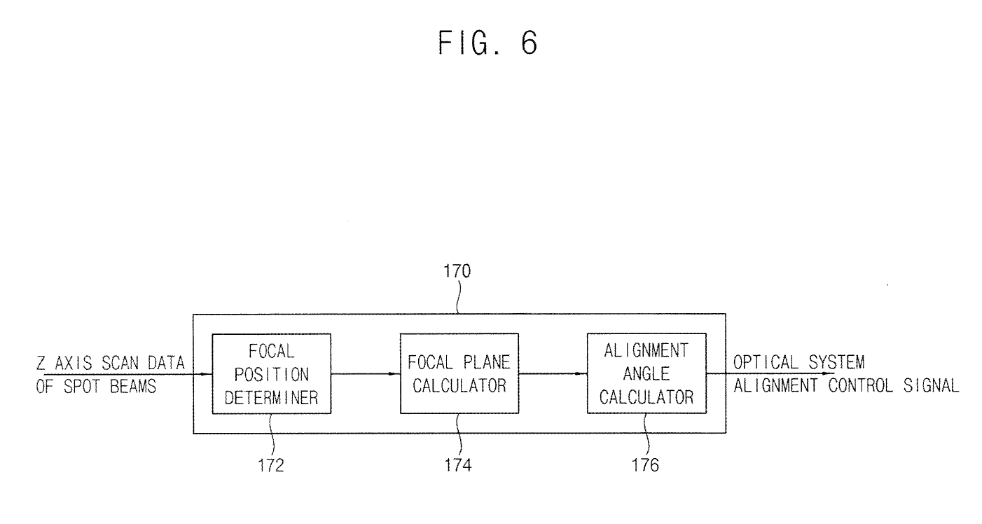

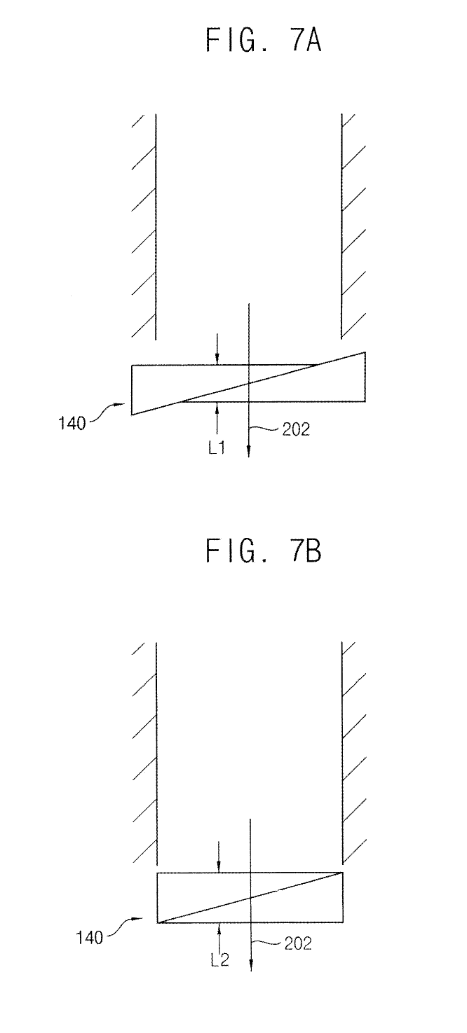

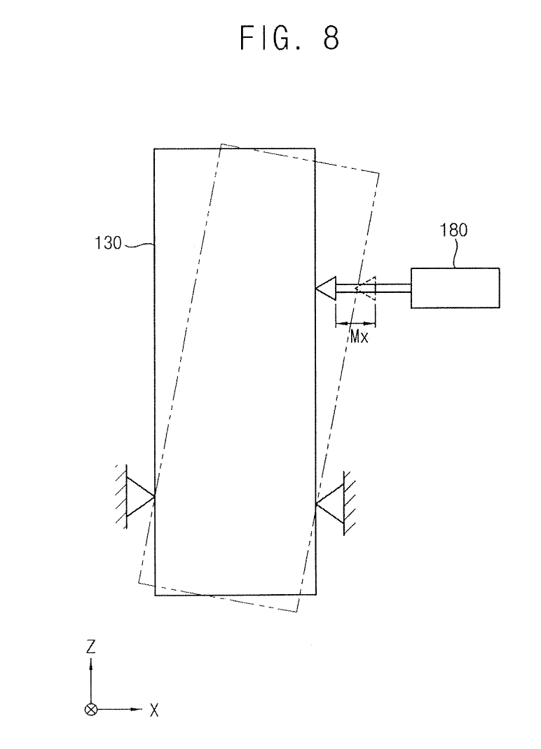

FIG. 6 is a block diagram illustrating a controller of the maskless exposure apparatus in FIG. 1. FIGS. 7A and 7B are views illustrating prism optical device of the maskless exposure apparatus in FIG. 1. FIG. 8 is a view illustrating an alignment actuator of the maskless exposure apparatus in FIG. 1.

Referring to FIGS. 1, 2 and 6 to 8, a control apparatus of a maskless exposure apparatus, may include a beam measure system 160 to measure focal positions on Z axis of spot beams 202 irradiated from an optical system 130 perpendicular to an object surface as a reference surface, a controller 170 to calculate a focal plane of the spot beams 202 from the measured focal positions and output an alignment control signal based on an angle error between the focal plane and the object surface for controlling an angle of the optical system 130, and an alignment actuator 180 to adjust the angle of the optical system 130 according to the alignment control signal. Additionally, the control apparatus of a maskless exposure apparatus may further the prism optical device 140 to scan the spot beam 202 in the Z axis in order to obtain information of the spot beam on the Z axis.

In example embodiments, the controller 170 may include a focal position determiner 172, a focal plane calculator 174, and an alignment angle calculator 176. The controller 170 may calculate the focal plane of a plurality of the spot beams irradiated from the optical system 130 and may control the alignment actuator 180 in order to adjust the angle of the optical system 130 based on the error information between the focal plane and the reference surface.

The focal position determiner 172 may receive Z axis scan data of the spot beams from the beam measurement system 160 and determine a Z axis focal position (optimal Z position value) of each of the spot beams from the Z axis scan data. The beam measurement system 160 may measure some spot beams selected from a plurality of spot beams irradiated from the optical system 130, e.g., not all spot beams output from the optical system 130 may be monitored. For example, a matrix of spot beams sufficient to provide information about the focal plane may be used.

Referring to FIGS. 7A and 7B, the prism optical device 140 may include a pair of wedge prisms to slidably move from each other. The wedge prisms may move relative to each other to change an optical length therethrough to thereby perform a depth scan in an optical axis direction (Z direction) on the spot beam. As the pair of wedge prisms slide along the X axis toward each other, a first light length L1 of FIG. 7A is changed into a second light length L2 of FIG. 7B, thereby caging a focal point of each spot beam along the Z axis.

Geometry information or intensity information of the spot beam detected by the Z axis scan in the beam measurement system 160 may be input to the focal position determiner 172 of the controller 170. Alternatively, while moving the optical system 130 along the Z axis or moving the beam measurement system 160 along the optical axis direction (Z direction), the geometry information or intensity information of the spot beam may be measured.

The focal position determiner 172 may determine the focal positions using the geometry information or intensity information of the spot beam. For example, geometry information data or intensity information data of the spot beam may be curve fitted to determine the Z axis focal position (optimal Z position value) of the spot beam.

In one embodiment, diameter data of the spot beam as the geometry information may be obtained through the Z axis scan. In this case, a polynomial expression best fit for the diameter data of the spot beam and a Z position value having a minimum value may be determined as the Z axis focal position.

In other embodiment, intensity data per pixel of the spot beam as the intensity information may be obtained through the Z axis scan. In this case, a polynomial expression best fit for the intensity data of the spot beam, and a Z position value having a maximum value may be determined as the Z axis focal position.

The focal plane calculator 174 may calculate the focal plane from the determined Z axis focal positions. The focal plane calculator 174 may calculate the focal plane from the determined Z axis focal positions using least square method.

The alignment angle calculator 176 may output the alignment control signal based on an angle error between the focal plane and the reference surface for controlling an angle of the optical system 130. The alignment angle calculator 176 may determine an X axis alignment movement amount (Mx) and a Y axis alignment movement amount (My) based on an angle difference between a normal vector of the focal plane and a normal vector of the object surface.

As illustrated in FIG. 8, the alignment actuator 180 may move the optical system 130 by the determined alignment amount. For example, the alignment actuator 180 may move the optical system 130 by the X axis alignment movement amount (Mx) and the Y axis alignment movement amount (My).

As mentioned above, the control apparatus of a maskless exposure apparatus may calculate the focal plane of a plurality of the spot beams irradiated from the optical system 130 and adjust an angle, e.g., relative to the Z axis or a normal vector of the object surface, i.e., the reference surface, of the optical system 130 based on the error information between the focal plane and the reference surface. Accordingly, a focal surface of the spot beams may be aligned to be parallel with a surface of a substrate to be exposed, to thereby improve the degree of precision of the exposure apparatus. Further alignment of each optical system 130, as illustrated in FIG. 2, may be separately controlled.

Hereinafter, a control method of aligning an optical system of a maskless exposure apparatus using the control apparatus of the maskless exposure apparatus will be explained.

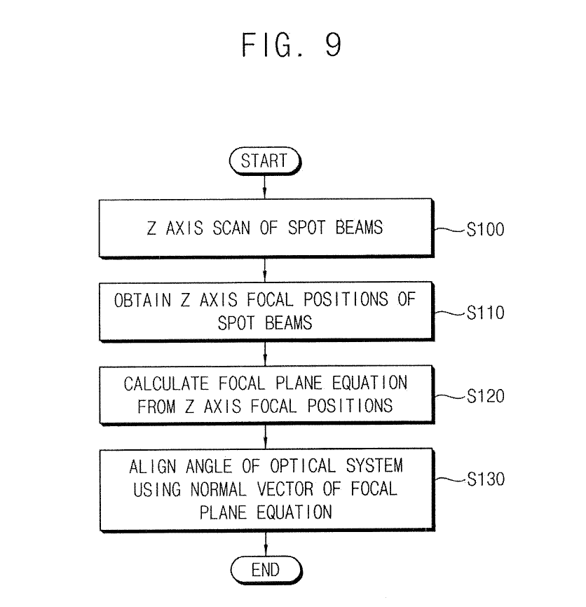

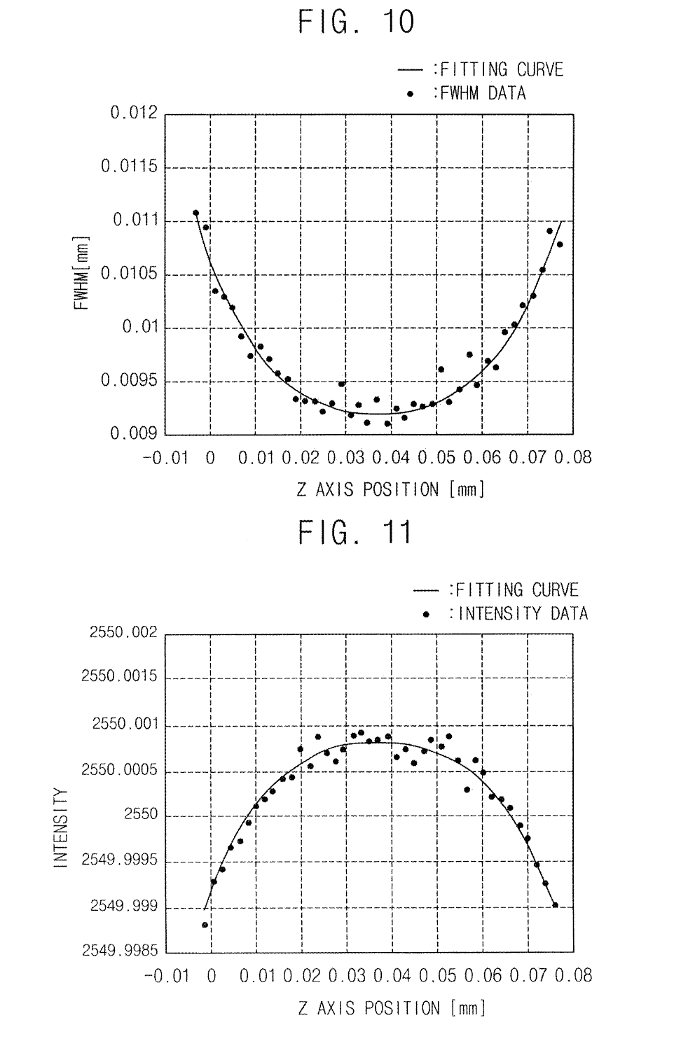

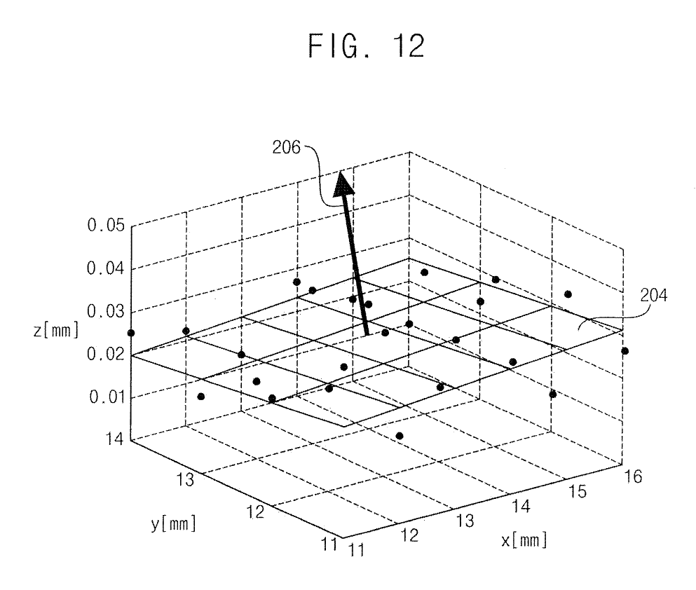

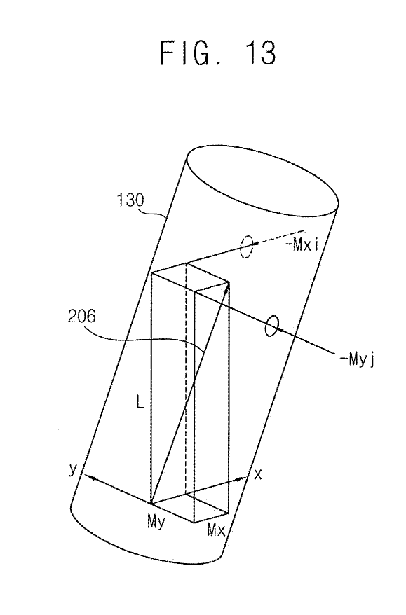

FIG. 9 is a flow chart illustrating a control method of an exposure apparatus in accordance with example embodiments. FIG. 10 is a graph illustrating a diameter of a spot beam with respect to Z axis position. FIG. 11 is a graph illustrating an intensity of a spot beam with respect to Z axis position. FIG. 12 is a graph illustrating a focal plane calculated from focal positions. FIG. 13 is a graph illustrating an alignment movement amount determined using a normal vector of the focal plane.

Referring to FIGS. 2 and 9 to 12, first, in a first operation S100, some of a plurality of spot beams irradiated from an optical system 130 may be selected, and a Z axis scan may be performed on the selected spot beams. In example embodiments, the beam measurement system 160 may move under a corresponding optical system 130, and the optical system 130 may irradiate a plurality of spot beams 202 onto a reference surface of the beam measurement system 160.

For example, the spot beam may be scanned in the Z axis direction using the prism optical device 140 to measure geometry information or intensity information of the spot beam. Alternatively, while moving the optical system 130 along the Z axis or moving the beam measurement system 160 along the optical axis direction (Z direction), the geometry information or intensity information of the spot beam may be measured.

Then, in a second operation S110, focal positions of the spot beams may be obtained. First, position data (X axis focal position, Y axis focal position) of the spot beams in the XY plane may be obtained using a plurality of fiducial marks FM of a fiducial BMS mark array (FBA), and Z axis focal positions may be determined using the geometry information or intensity information of the spot beam.

As illustrated in FIG. 10, diameter data of the spot beam as the geometry information may be obtained through the Z axis scan. A polynomial expression best fitted for the diameter data of the spot beam may be calculated by curve fitting, and a Z position value having a minimum value may be determined as a Z axis focal position. The polynomial expression may be represented by following equation (1).

$$f ( z ) = {a}_{0} + {a}_{a} z + {a}_{2} {z}^{2} + … {a}_{n} {z}^{n} = {\sum }_{k = 0}^{n} {a}_{k} {z}^{k} \\ ( n is an even number ) \qquad ( 1 )$$

As illustrated in FIG. 11, intensity data per pixel of the spot beam as the intensity information may be obtained through the Z axis scan. A polynomial expression best fit for the intensity data of the spot beam may be calculated by curve fitting, and a Z position value having a maximum value may be determined as a Z axis focal position.

Then, in a third operation S120, a plane equation may be calculated from the focal positions. As illustrated in FIG. 12, an equation of a focal plane 204 may be calculated from the focal positions using least square method. A focal surface formed by focal points of the spot beams may be approximately modeled into the focal plane 204 by the least square method as follows.

The equation of the focal plane 204 may be defined by following equation (2).

z=c+mₓx+m_{y}y (2)

An error between the focal position and the focal plane may be represented by following equations (3) and (4).

$$\begin{matrix}{d}_{i}^{2} = \frac{\vert {m}_{x} {x}_{i} + {m}_{y} {y}_{i} - {z}_{i} + c \vert}{\sqrt{{m}_{x}^{2} + {m}_{y}^{2} + 1}} \approx {\vert {m}_{x} {x}_{i} + {m}_{y} {y}_{i} - {z}_{i} + c \vert}^{2} & ( 3 ) \\ D = {\sum }_{i = 1}^{M \times N} {d}_{i}^{2} & ( 4 )\end{matrix}$$

Values of mₓ, m_{y}, c that minimize equation (4) may be obtained by the following equation (5).

$$[ \begin{matrix}{m}_{x} \\ {m}_{y} \\ c\end{matrix} ] = {[ \begin{matrix}\sum {x}_{i}^{2} & \sum {x}_{i} {y}_{i} & \sum {x}_{i} \\ \sum {x}_{i} {y}_{i} & \sum {y}_{i}^{2} & \sum {y}_{i} \\ \sum {x}_{i} & \sum {y}_{i} & \sum 1\end{matrix} ]}^{- 1} \cdot [ \begin{matrix}\sum {x}_{z} {z}_{i} \\ \sum {y}_{z} {z}_{i} \\ \sum {z}_{i}\end{matrix} ] \qquad ( 5 )$$

Thus, a focal plane equation may be calculated from the focal positions. In here, a normal vector 206 may be obtained from the focal plane equation. The normal vector 206 may be represented by following equation (6).

\vec{n}=±[mₓ m_{y}−1] (6)

Then, in a fourth operation S130, an angle of the optical system 130 may be aligned using the normal vector 206 of the focal plane equation. The angle of the optical system 130 may be aligned based on an angle difference between the normal vector 206 of the focal plane 204 and a normal vector of the reference surface.

As illustrated in FIG. 13, an X axis alignment movement amount (−Mxi) and a Y axis alignment movement amount (−Myj) may be determined based on the angle difference between the normal vector 206 of the focal plane 204 and a normal vector of the object surface.

An angle in X direction of the normal vector 206 may be obtained by following equation (7).

$$cos {α}_{x} = \frac{{M}_{x}}{\sqrt{{M}_{x}^{2} + {M}_{y}^{2} + {L}^{2}}} = \frac{s \cdot {m}_{x}}{\sqrt{{s}^{2} ( {m}_{x}^{2} + {m}_{y}^{2} ) + {L}^{2}}} \approx \frac{s \cdot {m}_{x}}{L} \qquad ( 7 )$$

Here, s is a scale factor, and is represented by following equation (8).

$$s = \frac{L}{{m}_{x}} \cdot {u}_{s} \approx \frac{L}{{m}_{x}} \cdot {m}_{x} = L \qquad ( 8 )$$

Accordingly, the X axis alignment movement amount (-Mxi) may be represented by following equation (9) and similarly the Y axis alignment movement amount (-Myj) may be represented by following equation (10).

Mₓ=s·mₓ≈L·mₓ (9)

M_{y}=s·m_{y}≈L·m_{y} (10)

Referring again to FIG. 8, the alignment actuator 180 may adjust an angle of the optical system 130 according to an alignment control signal output based on the calculated angle error, that is, alignment movement amount.

Above-mentioned operations may be reiterated until the optical system 130 is positioned within an allowable error. As mentioned above, in the control method of an exposure apparatus, the focal plane of a plurality of the spot beams irradiated from the optical system 130 may be calculated and an angle of the optical system 130 may be adjusted based on the error information between the focal plane and the reference surface. Accordingly, a focal surface of the spot beams may be aligned to be parallel with a surface of a substrate to be exposed, to thereby improve the degree of precision of the exposure apparatus.

A virtual mask pattern may be transferred to a substrate such as a glass substrate and a semiconductor wafer using a maskless exposure apparatus in accordance with example embodiments. For example, in order to form a circuit layer on the wafer, a photoresist layer may be deposited on the wafer, and a mask pattern of the photomask may be transferred to the photoresist layer using the maskless exposure apparatus. Then, a developing process may be performed on the photoresist layer to form a photoresist pattern, and an etch process may be performed using the photoresist pattern to form a desired circuit pattern on the wafer.

A display device, a semiconductor device, etc., may be manufactured by the exposure apparatus. For example, the display device may include an organic light emitting display device. The semiconductor device may include fin field effect transistor (finFET), dynamic random access memory (DRAM), vertical NAND, etc. The devices may be applied to a computer, a portable computer, a laptop computer, a personal portable terminal, a tablet, a cell phone, a digital music player, etc.

According to example embodiments, a focal plane of a plurality of spot beams irradiated from an optical system may be calculated and an angle of the optical system may be adjusted based on error information between the focal plane and a reference surface. Accordingly, a focal surface of the spot beams may be aligned parallel with a surface of a substrate to be exposed, to thereby improve the degree of precision of the exposure apparatus.

The methods and processes described herein may be performed by code or instructions to be executed by a computer, processor, manager, or controller. Because the algorithms that form the basis of the methods (or operations of the computer, processor, or controller) are described in detail, the code or instructions for implementing the operations of the method embodiments may transform the computer, processor, or controller into a special-purpose processor for performing the methods described herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, or controller which is to execute the code or instructions for performing the method embodiments described herein.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of controlling an exposure apparatus, the method comprising:
irradiating a plurality of spot beams from an optical system onto a reference surface;
obtaining focal positions of at least some spot beams of the plurality of spot beams on Z axis perpendicular to the reference surface;
calculating a focal plane of the at least some of the spot beams from the focal positions; and
aligning an angle of the optical system relative to the reference surface based on an angle error between the focal plane and the reference surface.

2. The method as claimed in claim 1, wherein irradiating the plurality of the spot beams from the optical system includes:
modulating light emitted from a light source into light having a mask pattern; and
projecting the modulated light into the plurality of the spot beams onto the reference surface through a plurality of array lenses.

3. The method as claimed in claim 2, wherein modulating into the light having the mask pattern includes using a spatial light modulator of the optical system.

4. The method as claimed in claim 1, wherein obtaining the focal positions of at least some spot beams on the Z axis includes:
Z axis scanning the plurality of spot beams respectively to obtain information of the at least some spot beams with respect to the Z axis; and
determining the focal positions on an optical axis from the information of the at least some spot beams.

5. The method as claimed in claim 4, wherein Z axis scanning the plurality of spot beams respectively includes moving the plurality of spot beams in the Z axis using a prism optical device.

6. The method as claimed in claim 4, wherein determining the focal positions on the optical axis from the information of the at least some spot beams includes determining the focal positions using geometry information or intensity information of the at least some spot beams detected on the reference surface by Z axis scanning.

7. The method as claimed in claim 6, wherein using the geometry information or intensity information of the spot beam includes curve fitting geometry information data or intensity information data of the at least some spot beams.

8. The method as claimed in claim 1, wherein calculating the focal plane of the at least some spot beams from the focal positions includes calculating an equation of the focal plane from the focal positions using least square method.

9. The method as claimed in claim 1, wherein aligning the angle of the optical system based on the angle error between the focal plane and the reference surface includes aligning the angle of the optical system on an angle difference between a normal vector of the focal plane and a normal vector of the reference surface.

10. The method as claimed in claim 1, wherein aligning the angle of the optical system includes driving an alignment actuator to adjust the angle of the optical system in order to compensate the angle error.

11. A method of controlling an exposure apparatus, the method comprising:
irradiating a plurality of spot beams from an optical system onto a reference surface;
scanning the plurality of spot beams in a Z axis respectively to obtain information of at least some spot beams of the plurality of spot beams on the Z axis perpendicular to the reference surface;
determining focal positions on an optical axis from the information of the at least some spot beams;
calculating a focal plane of the at least some spot beams from the focal positions; and
aligning an angle of the optical system relative to the reference surface based on an angle error between the focal plane and the reference surface.

12. The method as claimed in claim 11, wherein irradiating the plurality of the spot beams from the optical system includes:
modulating light emitted from a light source into a light having a mask pattern; and
projecting the modulated light into the plurality of the spot beams onto the reference surface through a plurality of array lenses.

13. The method as claimed in claim 11, wherein scanning the plurality of spot beams in the Z axis respectively includes moving the spot beam in the Z axis using a prism optical device.

14. The method as claimed in claim 13, wherein determining the focal positions on the optical axis from the information of the at least some spot beams includes determining the focal positions using geometry information or intensity information of the at least some spot beams detected on the reference surface by scanning.

15. The method as claimed in claim 14, wherein aligning the angle of the optical system based on the angle error between the focal plane and the reference surface includes aligning the angle of the optical system on an angle difference between a normal vector of the focal plane and a normal vector of the reference surface.

16. An apparatus to control an exposure apparatus, comprising;
a beam measurement system to measure focal positions of at least some spot beams of a plurality of spot beams irradiated from an optical system along a Z axis perpendicular to an object surface;
a controller to calculate a focal plane of the at least some spot beams from the measured focal positions and output an alignment control signal based on an angle error between the focal plane and the object surface for controlling an angle of the optical system; and
an alignment actuator to adjust the angle of the optical system relative to the object surface according to the alignment control signal.

17. The apparatus as claimed in claim 16, wherein the optical system includes:
a light modulation element to modulate light emitted from a light source into light having a mask pattern; and
a plurality of array lenses to separate the modulated light into the plurality of spot beams and to project onto the object surface.

18. The apparatus as claimed in claim 16, further comprising a prism optical device to scan the plurality of spot beams in the Z axis in order to obtain information of the spot beam on the Z axis.

19. The apparatus as claimed in claim 18, wherein the controller is to determine the focal positions using geometry information or intensity information of the at least some spot beams detected on the object surface by the Z axis scan.

20. The apparatus as claimed in claim 16, wherein the controller is to:
calculate the focal plane from the focal positions using least square, and
control the angle of the optical system based on an angle difference between a normal vector of the focal plane and a normal vector of the object surface.
